(19) United States
(12) Patent Application Publication
(10) Pub. No.: US 2025/0261402 A1
(43) Pub. Date: Aug. 14, 2025

(54) POWER SEMICONDUCTOR DEVICES AND METHODS OF FABRICATING THE SAME

(71) Applicant: Samsung Electronics Co., Ltd., Suwon-si (KR)

(72) Inventors: Gyeongseon PARK, Suwon-si (KR); Mingu Ko, Suwon-si (KR); Youngcheol Kim, Suwon-si (KR); Jongseob Kim, Suwon-si (KR); Taehun Kim, Suwon-si (KR); Jeongin Noh, Suwon-si (KR); Doohyung Cho, Suwon-si (KR)

(73) Assignee: Samsung Electronics Co., Ltd., Suwon-si (KR)

(21) Appl. No.: 19/008,226

(22) Filed: Jan. 2, 2025

(30) Foreign Application Priority Data
Feb. 8, 2024 (KR) 10-2024-0019951

(51) Int. Cl. H10D 30/66; H10D 30/01; H10D 62/10; H10D 62/17; H10D 62/80; H10D 62/832; H10D 64/27

(52) U.S. Cl. CPC H10D 30/668; H10D 62/124; H10D 62/393; H10D 62/8325; H10D 62/871; H10D 64/518; H10D 30/0297

(57) ABSTRACT

Provided is a power semiconductor device, including a silicon carbide (SiC) substrate having a first conductivity type, a drift layer including a first conductivity type SiC on the SiC substrate, a well region having a second conductivity type on the drift layer, a source region having the first conductivity type on the well region, a gate electrode on a portion of the drift layer and a portion of the well region, a gate insulating layer between the gate electrode and the well region, an interlayer insulating layer on the gate electrode and the source region, a source electrode on the interlayer insulating layer connected to the source region through the interlayer insulating layer, a conductive substrate on a lower surface of the SiC substrate, and a bonding metal layer between the SiC substrate and the conductive substrate.

### CROSS-REFERENCE TO RELATED APPLICATION

This application claims priority to Korean Patent Application No. 10-2024-0019951, filed on Feb. 8, 2024 in the Korean Intellectual Property Office, the inventive concept of which is incorporated herein by reference in its entirety.

### BACKGROUND

### 1. Field

Embodiments of the present disclosure relate to a power semiconductor device and a method of manufacturing the same.

### 2. Description of Related Art

The power semiconductor device is a semiconductor device operating in high voltage and high current environments, and is used in fields requiring high power switching, such as power conversion, power converters, inverters, and the like. The power semiconductor device basically requires withstand voltage characteristics against high voltages, and recently, additionally require high-speed switching operations. Accordingly, a power semiconductor device using SiC, which has superior voltage resistance characteristics compared to silicon (Si), is being researched.

### SUMMARY

One or more embodiments provide a power semiconductor device having improved electrical characteristics.

One or more embodiments also provide a method of manufacturing a power semiconductor device having improved electrical characteristics.

According to an aspect of one or more embodiments, there is provided a power semiconductor device, including a silicon carbide (SiC) substrate having a first conductivity type, a drift layer including a first conductivity type SiC on the SiC substrate, a well region having a second conductivity type on the drift layer, a source region having the first conductivity type on the well region, a gate electrode on a portion of the drift layer and a portion of the well region, a gate insulating layer between the gate electrode and the well region, an interlayer insulating layer on the gate electrode and the source region, a source electrode on the interlayer insulating layer connected to the source region through the interlayer insulating layer, a conductive substrate on a lower surface of the SiC substrate, and a bonding metal layer between the SiC substrate and the conductive substrate.

According to another aspect of one or more embodiments, there is provided a power semiconductor device, including a silicon carbide (SiC) substrate having a first conductivity type and a thickness less than or equal to 100 μm, a drift layer including a first conductivity type SiC on the SiC substrate, a well region having a second conductivity type extending into the drift layer from an upper surface of the drift layer, a source region having the first conductivity type extending into the well region from an upper surface of the well region, a gate electrode on a portion of the drift layer and a portion of the well region, a gate insulating layer between the gate electrode and the well region, an interlayer insulating layer on the gate electrode and the source region, a source electrode on the interlayer insulating layer connected to the source region through the interlayer insulating layer, a metal substrate on a surface of the SiC substrate, as the metal substrate being a drain electrode, and a bonding metal layer between the SiC substrate and the metal substrate.

According to still another aspect of one or more embodiments, there is provided a power semiconductor device, including a silicon carbide (SiC) substrate having a first conductivity type having a thickness less than or equal to 100 μm, a drift layer including a first conductivity type SiC on the SiC substrate, a well region having a second conductivity type extending into the drift layer from an upper surface of the drift layer, a source region having the first conductivity type extending into the well region from an upper surface of the well region, a gate electrode on a portion of the drift layer and a portion of the well region, a gate insulating layer between the gate electrode and the well region, an interlayer insulating layer on the gate electrode and the source region, a source electrode on the interlayer insulating layer connected to the source region through the interlayer insulating layer, a low-resistance semiconductor substrate on a surface of the SiC substrate, and doped with a first conductivity-type impurity, a bonding metal layer between the SiC substrate and the low-resistance semiconductor substrate, a metal-semiconductor compound layer on a surface of the low-resistance semiconductor substrate, and a drain electrode layer on the metal-semiconductor compound layer.

According to further still another aspect of one or more embodiments, there is provided A method of manufacturing a power semiconductor device, including forming a plurality of power semiconductor devices on a first surface of a silicon carbide (SiC) substrate having a first conductivity type, bonding a carrier substrate to the first surface of the SiC substrate using a temporary bonding layer, performing a grinding operation on a second surface, opposite to the first surface, of the SiC substrate to reduce a thickness of the SiC substrate, applying a first bonding metal layer to the second surface of the SiC substrate, and providing a conductive substrate having a first surface on which a second bonding metal layer is formed, bonding the conductive substrate to the second surface of the SiC substrate using the first bonding metal layer and the second bonding metal layer, removing the carrier substrate from the first surface of the SiC substrate by applying energy to the temporary bonding layer, and cutting the SiC substrate to which the conductive substrate is bonded into the plurality of power semiconductor devices.

### BRIEF DESCRIPTION OF DRAWINGS

The above and other aspects, features, and advantages of embodiments will be more clearly understood from the following detailed description, taken in conjunction with the accompanying drawings:

FIG. 1 is a schematic perspective view illustrating a power semiconductor device according to one or more embodiments;

FIG. 2 is a plan view illustrating a portion of regions A1 of the power semiconductor device shown in FIG. 1, and FIG. 3 is a side cross-sectional view of the power semiconductor device shown in FIG. 2 taken along line I1-I1′;

FIG. 4 is a schematic perspective view illustrating a power semiconductor device according to one or more embodiments;

FIG. 5 is a plan view illustrating a portion of regions A2 of the power semiconductor device shown in FIG. 4, and FIG. 6 is a side cross-sectional view of the power semiconductor device shown in FIG. 5 taken along line 12-12′;

FIGS. 7A, 7B, and 7C are cross-sectional views for each main operation illustrating some operations of the method of manufacturing a power semiconductor device according to one or more embodiments;

FIGS. 8A and 8B are a perspective view and a cross-sectional view, respectively, illustrating an example of the grinding operation of FIG. 7C;

FIGS. 9A, 9B, 9C, and 9D are cross-sectional views for each main operation illustrating some other operations of the method of manufacturing a power semiconductor device according to one or more embodiments; and

FIGS. 10A, 10B, 10C, 10D, and 10E are cross-sectional views for each main operation illustrating some other operations of the method of manufacturing a power semiconductor device according to one or more embodiments.

### DETAILED DESCRIPTION

Hereinafter, various embodiments will be described in detail with reference to the attached drawings.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

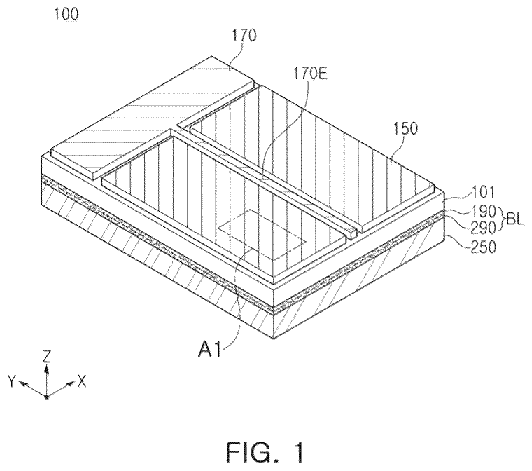

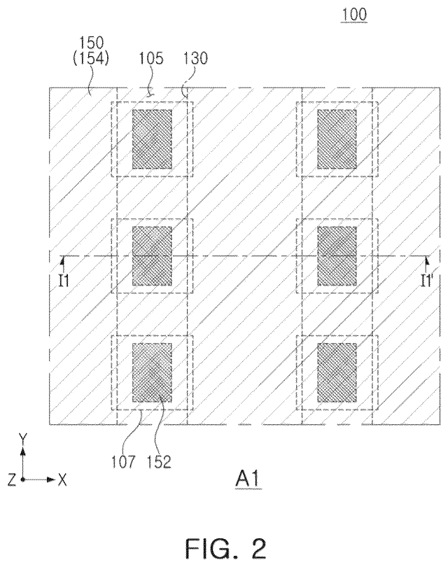

FIG. 1 is a schematic perspective view illustrating a power semiconductor device according to one or more embodiments, and FIGS. 2 and 3 are a plan view and a side view illustrating a portion of regions Al of the power semiconductor device shown in FIG. 1. Here, FIG. 3 is a side cross-sectional view of the power semiconductor device shown in FIG. 2 taken along line I1-I1′.

Referring to FIGS. 1 to 3, a power semiconductor device 100 according to an embodiment may include a first conductivity-type substrate 101, a drift layer of a first conductivity type 102 on the first conductivity-type substrate 101, well regions 105 of a second conductivity type disposed in the drift layer of the first conductivity type 102, source regions 107 of the first conductivity type disposed in the well regions 105, a conductive substrate 250 disposed on a lower surface of the first conductivity-type substrate 101, and a bonding metal layer BL between the first conductivity-type substrate 101 and the conductive substrate 250.

A source electrode 150 and a gate electrode pad 170 may be disposed on an upper surface of the power semiconductor device 100. The source electrode 150 may be configured to be connected to the source regions 107, and the gate electrode pad 170 may be configured to be connected to the gate electrode 130. In an embodiment, the source electrode 150 may be divided into two electrodes, and the gate electrode pad 170 may have an electrode portion 170E extending between the two source electrode pads 150. However, embodiments are not limited thereto, and arrangement of the electrodes may be variously changed.

The conductive substrate 250 employed in the present embodiment may be used as a drain electrode along with the function of a support substrate. The conductive substrate 250 may include a metal or alloy substrate with lower resistivity than a resistivity of the first conductivity-type substrate 101. For example, the conductive substrate 250 may include copper (Cu), aluminum (Al), aluminum silicon carbide (AlSiC) substrate, copper molybdenum (CuMo), copper tungsten (CuW), Cu/CuMo/Cu, Cu/Mo/Cu, or Cu/W/Cu. In some example embodiments, the conductive substrate 250 may include CuW or Cu/Mo/Cu, which has relatively high electrical conductivity.

As described above, the conductive substrate 250 may be bonded to first conductivity-type substrate 101 having relatively high resistance by a bonding metal layer BL. In some embodiments, the bonding metal layer BL may include eutectic metals. For example, the bonding metal layer BL may include eutectic gold tin (AuSn), nickel tin (NiSn), silver tin (AgSn), chromium/nickel tin titanium gold (Cr/NiSnTiAu), titanium/platinum tin indium (Ti/PtSnIn), or titanium/platinum tin titanium gold (Ti/PtSnTiAu). The bonding metal layer BL may be a layer in which a first eutectic metal layer 190 disposed on a lower surface of the first conductivity-type substrate 101 and a second eutectic metal layer 290 disposed on an upper surface of the conductive substrate 250 are bonded by eutectic bonding. In some embodiments, the first and second eutectic metal layers 190 and 290 may include the same eutectic metal.

The first conductivity-type substrate 101 may be provided as a bulk wafer or an epitaxial layer. The first conductivity-type substrate 101 may include silicon carbide (SiC). The first conductivity-type substrate 101 may have a relatively thin thickness (e.g., less than or equal to 150 μm) through an operation of reducing the thickness such as grinding. For example, a thickness (t1) of the first conductivity-type substrate 101 may be less than or equal to 100 μm, and in some embodiments, may be less than or equal to 80 μm. However, embodiments are not limited thereto, and the substrate 101 may include a group IV semiconductor material such as silicon (Si) or germanium (Ge), or a compound semiconductor material such as silicon germanium (SiGe), gallium arsenide (GaAs), indium arsenide (InAs), or indium phosphide (InP). The first conductivity-type substrate 101 may include first conductivity-type impurities and thus may have a first conductivity type. In some embodiments, the first conductivity type may be, for example, N-type, and the first conductivity-type impurities may be N-type impurities, for example, nitrogen (N) and/or phosphorus (P). In some embodiments, the first conductivity type may be, for example, P-type, and the first conductivity-type impurities may be, for example, P-type impurities such as aluminum (Al).

The drift layer 102 may be disposed on the substrate 101. The drift layer 102 may include the same SiC as the first conductivity-type substrate. The drift layer 102 may be an epitaxial layer grown on the substrate 101. In some embodiments, a thickness (t2) of the drift layer may be in the range of 2 μm to 20 μm. The drift layer 102 may include first conductivity-type impurities and thus may have the first conductivity type. A concentration of the first conductivity-type impurities in the drift layer 102 may be lower than a concentration of first conductivity-type impurities in the substrate 101. In some embodiments, the first conductivity-type impurities in the substrate 101 and the drift layer 102 may include the same or different elements.

The plurality of well regions 105 may be disposed at a predetermined depth from an upper surface of the drift layer 102. In the embodiment, as shown in FIG. 2, the plurality of well regions may be arranged to be spaced apart from each other in a first direction (e.g., X-direction) and have a stripe pattern extending in a second direction (e.g., Y-direction). The plurality of well regions 105 may include a semiconductor material, for example, SiC. The plurality of well regions 105 may be regions in which second conductivity-type impurities are ion-implanted into an upper region of the drift layer 102. For example, the second conductivity type may be P-type, and the second conductivity-type impurities may be P-type impurities such as aluminum (Al). In some embodiments, each of the plurality of well regions 105 may include a plurality of regions having different doping concentrations.

In the embodiment, the plurality of source regions 107 may be disposed to be spaced apart from each other in a second direction (e.g., Y-direction) within each of the well regions 105. The plurality of source regions 107 may be disposed at a predetermined depth from upper surfaces of each of the well regions 105. A thickness of the plurality of source regions 107 is smaller than a thickness of the well regions 105. The source regions 107 may include, for example, SiC. The source regions 107 may be regions in which first conductivity-type impurities are ion-implanted into the upper regions of the well regions 105. For example, the first conductivity type may be N-type and may include the first conductivity-type impurities described above. A concentration of first conductivity-type impurities in the source region 107 may be higher than a concentration of first conductivity-type impurities in the drift layer 102, but embodiments are not limited thereto.

Referring to FIG. 3, the well contact region 109 may be disposed between the well region 105 and the source electrode 150. In the embodiment, the well contact regions 109 may penetrate the source regions 107 and be connected to the well regions 105. A voltage applied from the source electrode 150 may be applied to the well region through the well contact region 109. The well contact region 109 may include a semiconductor material, for example, SiC. The well contact region 109 may be a region having the second conductivity type, and may include the second conductivity-type impurities described above. A concentration of the second conductivity-type impurities in the well contact region 109 may be higher than a concentration of the second conductivity-type impurities in the well region 105.

In the embodiment, the gate electrodes 130 may have a stripe pattern extending in a second direction (e.g., Y-direction) between the well regions 105, as shown in FIG. 2. The gate electrodes 130 may be disposed on the drift layer 102, and both side regions of the gate electrodes 130 may be located on one region of the source regions 107 and one region of the well regions 105. As shown in FIG. 3, regions on the both side regions of the gate electrode 130 may overlap each of the one region of the source region 107 and the well region 105 in a vertical direction (e.g., Z-direction). The gate electrode 130 may be spaced apart from the source region 107, the well region 105, and the drift layer 102 by the gate insulating layer 120.

The gate electrode 130 may include a conductive material, for example, a semiconductor material such as doped polycrystalline silicon, titanium nitride (TiN), tantalum nitride (TaN), or tungsten nitride (WN), a metal nitride such as titanium nitride (TiN), tantalum nitride (TaN), or tungsten nitride (WN), and/or a metal material such as aluminum (Al), tungsten (W), molybdenum (Mo), or the like.

The gate insulating layers 120 may be disposed on a lower surface of the gate electrode 130. The gate insulating layer 120 may extend onto the source region 107, the well region 105 outside the source region 107, and the drift layer 102. As shown in FIG. 3, the gate insulating layer 120 may be disposed between the source region 107 and the well region 105, and the drift layer 102 and the gate electrode 130. In some example embodiments, the gate insulating layers 120 may include a plurality of gate insulating films. For example, the gate insulating layers 120 may include oxide, nitride, or a high-k material. The high dielectric constant material may refer to a dielectric material having a higher dielectric constant than a silicon oxide film (SiO₂). The high dielectric constant material may refer to a dielectric material having a higher dielectric constant than a silicon oxide film (SiO₂). The high dielectric constant material may be any one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaAlₓO_{y}), hafnium aluminum oxide (HfAlₓO_{y}), and praseodymium oxide (Pr₂O₃).

When the power semiconductor device 100 is operated, a channel region having a transistor may be formed in both side regions adjacent to each of the gate electrodes 130 in the plurality of well regions 105. The channel region may be a region including the side surface of the well regions 105 or adjacent to the side surface thereof. The channel region may face the gate electrode 130 with the gate insulating layer 120 interposed therebetween. As an example, the channel region may exist in an upper region of the well region 105 overlapping the gate electrode 130 in the vertical direction (e.g., Z-direction).

The power semiconductor device 100 according to the embodiment further includes an interlayer insulating layer 140 on the gate electrode 130. The interlayer insulating layer 140 may cover and be provided on the gate electrodes 130, and may be disposed to expose a portion of each of the source regions 107. The interlayer insulating layer 140 may cover and be provided on an upper surface and a side surface of the gate electrode 130 and a side surface of the gate insulating layer 121. The interlayer insulating layer 140 may include an insulating material, and may include at least one of silicon oxide, silicon nitride, and silicon oxynitride.

As shown in FIGS. 2 and 3, the source electrode 150 may include an electrode layer disposed on the interlayer insulating layer 140 and electrically connected to the source regions 107.

The source electrode 150 may include an electrode layer 154 and a metal-semiconductor compound layer 152. The metal-semiconductor compound layer 152 may be formed on surfaces of the well region 105 and the well contact region 109 with which the electrode layer 154 contacts. The electrode layer 154 may include at least one of, for example, nickel (Ni), aluminum (Al), titanium (Ti), silver (Ag), vanadium (V), tungsten (W), cobalt (Co), and molybdenum (Mo), copper (Cu), and ruthenium (Ru). The metal-semiconductor compound layer 152 may include a metal element and a semiconductor element, for example, at least one of titanium silicide (TiSi), cobalt silicide (CoSi), molybdenum silicide (MoSi), lanthanium silicide (LaSi), nickel silicide (NiSi), tantalum silicide (TaSi), or tungsten silicon (Wsi).

As described above, the conductive substrate 250 employed in the embodiment may be used as a drain electrode along being used as a support substrate. The conductive substrate 250 includes a metal or alloy substrate with lower resistivity than a resistivity of the first conductivity-type substrate 101, and may be used as a substrate for an electrode bonded to the first conductivity-type substrate 101 with relatively high resistance by the bonding metal layer BL.

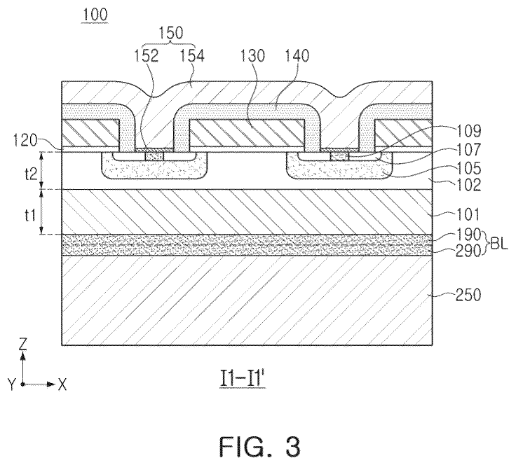

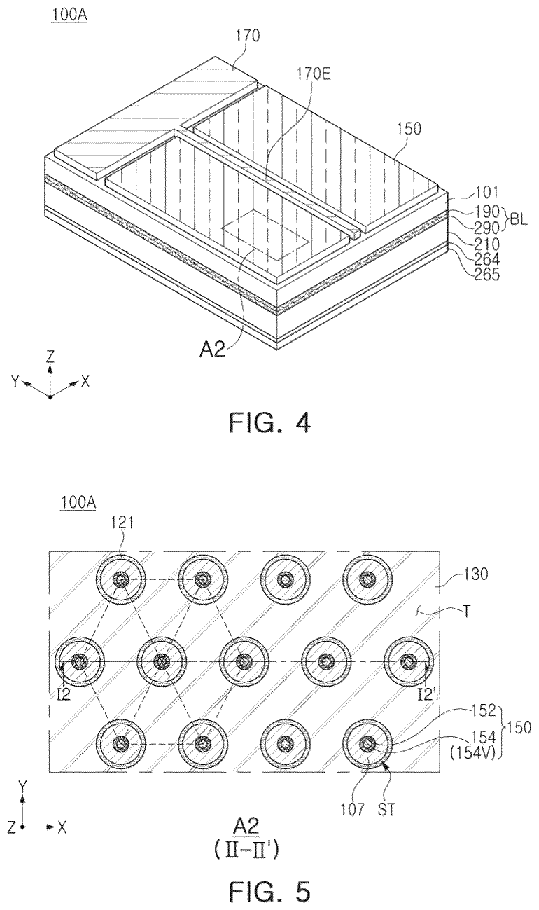

FIG. 4 is a schematic perspective view illustrating a power semiconductor device according to one or more embodiments, and FIGS. 5 and 6 are a plan view and a side cross-sectional view illustrating a portion of regions A2 of the power semiconductor device shown in FIG. 4. Here, FIG. 5 is a plan view of the power semiconductor device shown in FIG. 6 cut along the line II-II′, and FIG. 6 is a side cross-sectional view of the power semiconductor device shown in FIG. 5 cut along the line I2-I2′.

Referring to FIGS. 4 to 6, it can be understood that the power semiconductor device 100A according to the embodiment is similar to the power semiconductor device 100 shown in FIGS. 1 and 2 to 4, except that the power semiconductor device 100A includes a low-resistance semiconductor substrate 210 instead of a metal substrate as a conductive substrate, and the power semiconductor device 100A includes a plurality of stacks ST in the well region and the source region and a gate electrode 130 surrounding the plurality of stacks ST. In addition, unless otherwise stated, the components of the embodiment may be understood with reference to the description of the same or similar components of the power semiconductor device 100 shown in FIGS. 1 to 3.

The conductive substrate employed in the embodiment may include a low-resistance semiconductor substrate 210 doped with impurities. In some embodiments, the low-resistance semiconductor substrate 210 may be a silicon substrate having resistivity significantly lower (e.g., 10 or more times) than a resistivity of SiC, which is the first conductivity-type substrate 101. In some embodiments, the low-resistance semiconductor substrate 210 may be a silicon substrate doped with a specific conductivity-type impurity at a high concentration (e.g., greater than or equal to 10¹⁹/cm²). For example, the specific conductivity-type impurity may be an N-type impurity such as nitrogen (N), phosphorus (P), arsenic (As), antimony (Sb), or bismuth (Bi). The low-resistance semiconductor substrate 210 may have resistivity (@300K) of less than or equal to about 0.05 Ω·cm. For example, the low-resistance semiconductor substrate 210 may be a semiconductor substrate doped with N-type impurities to greater than equal to about 2×10¹⁹/cm².

The low-resistance semiconductor substrate 210 and the thinly ground first conductivity-type substrate 101 may be bonded to each other by a bonding metal layer BL. In some embodiments, the bonding metal layer BL may include a eutectic metal layer. For example, the bonding metal layer BL may include AuSn, NiSn, AgSn, Cr/NiSnTiAu, Ti/PtSnIn, or Ti/PtSnTiAu. The bonding metal layer BL may be a layer in which a first eutectic metal layer 190 disposed on the lower surface of the first conductivity-type substrate 101 and a second eutectic metal layer 290 disposed on the upper surface of the low-specific semiconductor substrate 210 are bonded by eutectic bonding. In some embodiments, the first and second eutectic metal layers 190 and 290 may include the same eutectic metal.

The power semiconductor device 100A employed in the embodiment may include a drain electrode layer 260 disposed on a lower surface of the low-resistance semiconductor substrate 210, and a metal-semiconductor compound layer 264 disposed between the low-resistance semiconductor substrate 210 and the drain electrode layer 260. The drain electrode layer 260 may include a metal material, for example, at least one of nickel (Ni), aluminum (Al), titanium (Ti), silver (Ag), vanadium (V), tungsten (W), cobalt (Co), molybdenum (Mo), copper (Cu), and ruthenium (Ru). The metal-semiconductor compound layer 124 may include a metal element and a semiconductor element, for example, at least one of TiSi, CoSi, MoSi, LaSi, NiSi, TaSi, or Wsi.

As described above, the thickness of the first conductivity-type substrate 101, which has a relatively high-resistance structure, may be reduced, and the conductive substrate, which has a relatively low resistance structure, may introduce the low-resistance conductive substrate 210, in addition to the metal substrate, so that driving voltage characteristics of the power semiconductor device 100A may be improved.

In the embodiment, stacks ST (also referred to as “cells”) of each of the plurality of well regions 105 and the plurality of source regions 107 have a pillar structure with rounded sides.

As shown in FIG. 5, in a plan view, each of the stacks ST may have a circular pillar structure with a circular cross-section. The cylindrical stacks ST may be arranged in a hexagonal shape at regular intervals. As shown in FIG. 6, the stacks ST employed in the embodiment may include an upper region of the drift layer 102. The power semiconductor device 100A according to the embodiment may further include a gate electrode 130 surrounding the stacks ST and filled between the stacks ST, and a gate insulating layer 121 disposed between the stacks ST and the gate electrode 130.

As described above, the plurality of stacks ST may have a pillar structure (e.g., a cylinder) due to a trench region T. This trench region T may have a depth extending from upper surfaces of the source regions 107 to a portion of regions of the drift layer 102 through the source regions 107 and the well regions 105. As described above, the trench region T may completely penetrate the well region 105, and a bottom of the trench region T may be provided by the drift layer 102. The trench region T provides a space in which a gate structure, that is, the gate insulating layer 120 and the gate electrode 130, are disposed.

Referring to FIG. 6, the gate insulating layer 121 may extend to a bottom of the trench region T. As described above, the gate insulating layer 121 may be disposed between the source region 107, the well region 105, and the drift layer 102 and the gate electrode 130. A bottom insulating portion 125 may be disposed on the gate insulating layer 121 at the bottom of the trench region T. The bottom insulating portion 125 may have a thickness greater than a thickness of the gate insulating layer 121. A bottom insulating portion 125 having a relatively large thickness may be disposed at the bottom of the trench region T, thereby preventing destruction of the gate insulating layer 121 due to an electric field formed in the drift layer 102. The bottom insulating portion 125 may include the same material as a material of the gate insulating layer 121. For example, the bottom insulating portion 125 may include oxide or nitride.

Contact vias 154V may each be disposed at approximately a central region of the stacks ST.

The electrode layer 154 used in the embodiment may have a plurality of contact vias 154V extending from upper surfaces of a plurality of source regions 107 to the plurality of well regions 105. The contact vias 154V employed in the embodiment may be formed deeper than the plurality of source regions 107. As described above, the source electrode 150 may be connected not only to the plurality of source regions 107 but also to the plurality of well regions 105 through the plurality of contact vias 154V.

In the embodiment, the source electrode 150 may reduce contact resistance by increasing an area in contact with a well region having a second conductivity type 105 through the contact vias 154V. As a result, the contact area through which diode current can flow when a reverse voltage is applied can be increased. As described above, the power semiconductor device 100A according to the embodiment may improve current capability ruggedness. In addition, the on-resistance between the drain electrode 160 and the source electrode 150 may be lowered through the contact vias 154V.

The well contact regions 109 may be disposed between the well region 105 and the source electrode 150, to allow a voltage from the source electrode 150 to be applied to the well region 105. The well contact region 109 may include a semiconductor material, for example, SiC. The well contact region 109 may be a region having the second conductivity type, and may include the second conductivity-type impurities described above. A concentration of the second conductivity-type impurities in the well contact region 109 may be higher than a concentration of the second conductivity-type impurities in the well region 105.

As previously described, the gate electrode 130 may be disposed in the trench region T to surround and be adjacent to the plurality of stacks ST, as shown in FIGS. 5 and 6. The gate insulating layer 121 may be disposed between the stacks ST, and the gate electrode 130.

The gate electrode 130 may overlap at least the well region 105 in a horizontal direction (e.g., X-or Y-direction). In the embodiment, the gate electrode 130 may overlap a portion of the drift region and a portion of the source region 107 in the horizontal direction.

As described above, the power semiconductor device 100A according to the embodiment may provide a gate all around structure in which the gate electrode 130 and the gate insulating layer 121 surround a side surface of the well region 107. As a result, the power semiconductor device 100 according to the embodiment may be secured with a large area of a channel region with improved electrical characteristics.

As described above, a method of significantly improving electrical characteristics such as on-resistance (Ron) may be applied to a power semiconductor device having various cell structures, by introducing a conductive substrate (metal substrate or low-resistance semiconductor substrate) while reducing the thickness of the SiC substrate, which is the first conductivity type.

A low-resistance semiconductor substrate 210 may also be introduced as a conductive substrate into the planar-type power semiconductor device 100 shown in FIGS. 1 to 3. In this case, the metal-semiconductor compound layer 264 and the drain electrode layer 260 may be additionally introduced. In addition, a metal substrate may also be introduced as a conductive substrate into the power semiconductor device 100 having the three-dimensional structure (or trench structure) shown in FIGS. 4 to 6.

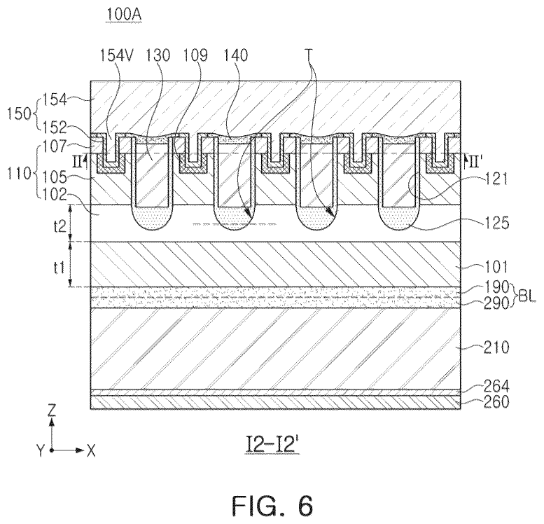

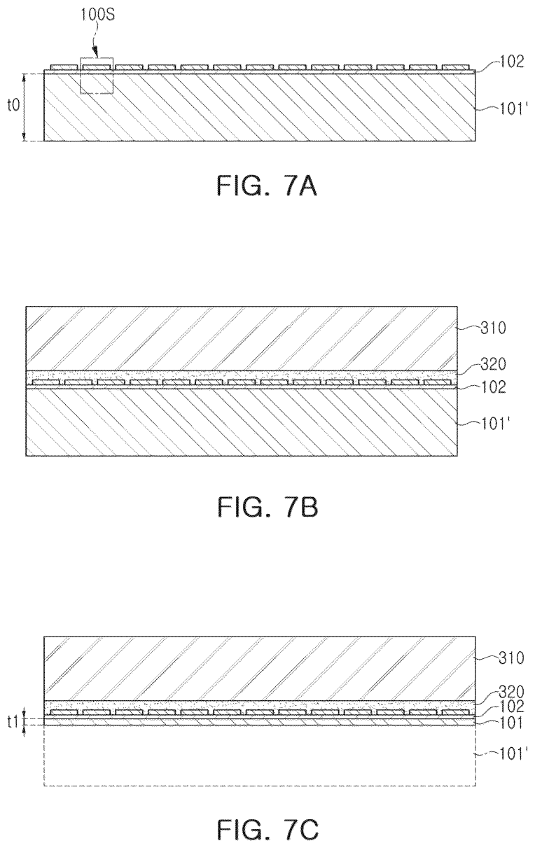

FIGS. 7A to 7C are cross-sectional views for each main operation illustrating operations of the method of manufacturing a power semiconductor device according to one or more embodiments. The operation illustrated in FIGS. 7A to 7C is an operation for reducing a thickness of a first conductivity-type substrate 101 of the method of manufacturing a power semiconductor device.

Referring to FIG. 7A, a plurality of power semiconductor devices 100S may be formed on an upper surface of a first conductivity-type substrate 101′.

The first conductivity-type substrate 101′ may have a drift layer having a first conductivity type 102, and the structures illustrated in FIGS. 3 and 6 may be formed on the drift layer having a first conductivity type 102 to form a plurality of desired plurality of power semiconductor device 100S. Here, the plurality of power semiconductor devices 100S may have a structure corresponding to one of the power semiconductor devices 100 and 100A of FIGS. 3 and 6, respectively. However, a thickness t0 of the first conductivity-type substrate 101′ corresponds to a thickness of a first wafer, and may be, for example, several hundred ums or more. For example, the first conductivity-type substrate 101′ may be a SiC wafer doped with N-type impurities.

Next, referring to FIG. 7B, a carrier substrate 310 may be bonded to an upper surface of the first conductivity-type substrate 101′ using a temporary bonding layer 320.

The temporary bonding layer 320 may include a photosensitive bonding layer. For example, the photosensitive adhesive layer may include photosensitive polyimide (PSPI). The carrier substrate 310 may include a light-transmitting substrate through which ultraviolet

(UV) light can be transmitted. The temporary bonding layer 320 may bond the carrier substrate 310 to the first conductivity-type substrate 101′ on which the plurality of power semiconductor devices 100S are formed. In some embodiments, the temporary bonding layer 320 may have a multi-layer structure including an adhesive layer and a release layer.

Next, referring to FIG. 7C, an operation of reducing the thickness to of the conductivity-type substrate 101′ to a desired thickness t1 is performed.

The operation of reducing the thickness of the substrate may be performed by grinding operation on a lower surface of the first conductivity-type substrate 101′. During the grinding operation, the first conductivity-type substrate 101 can be stably supported on the carrier substrate 310. In the present operation, the first conductivity-type substrate 101 formed of SiC, a high-resistance component, may be reduced to a sufficient thickness t1. The thickness (t1) of the final grinded conductivity-type substrate 101 may be 150 μm or less. In some example embodiments, the thickness t1 of the first conductivity-type substrate 101 may be 100 μm or less, or 80 μm or less. As described above, the electrical characteristics such as on-resistance of the high-resistance component can be greatly improved as the thickness of the first conductive type substrate is reduced.

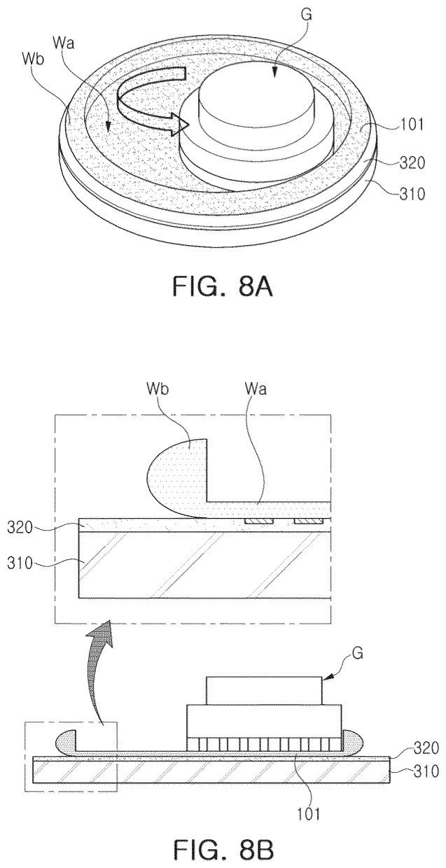

The grinding operation of the conductivity-type substrate that can be introduced in FIG. 7C may be performed in a TAIKO grinding operation shown in FIGS. 8A and 8B. FIGS. 8A and 8B are a perspective view and a cross-sectional view of the grinding operation of FIG. 7C illustrating an example, respectively

Referring to FIGS. 8A and 8B, an inner region Wa of the first conductivity-type substrate 101 is grinded using a grinder G. The inner region Wa of the first conductivity-type substrate 101 may include an active region in which a plurality of power semiconductor devices are formed. An edge region Wb of the first conductivity-type substrate 101 may include a portion of a certain width that is not grinded. The edge region Wb can facilitate handling of the thinned substrate even after the grinding operation, and prevent deformation problems such as warpage. For example, a width of the edge region Wb may be in the range of 1 mm to 5 mm.

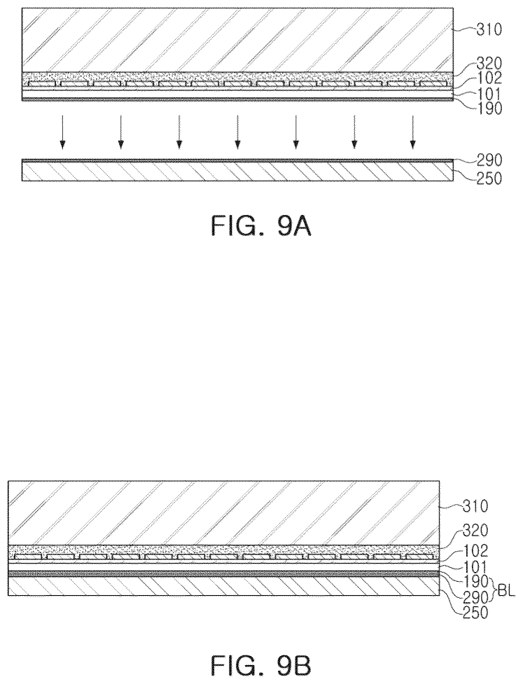

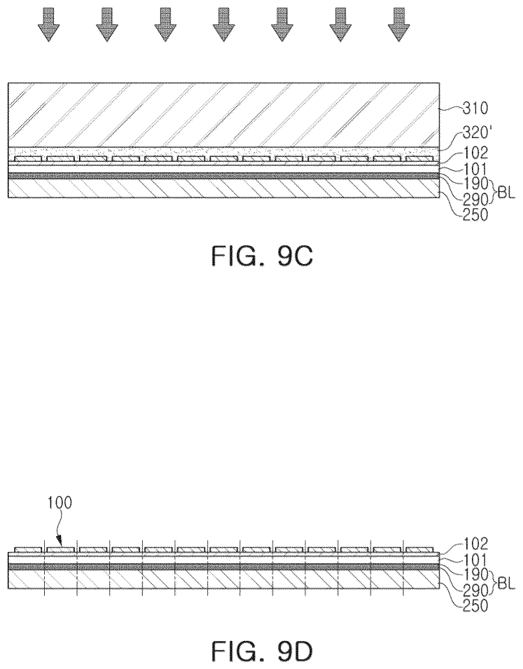

FIGS. 9A to 9D are cross-sectional views for each main operation illustrating some other operations of the method of manufacturing a power semiconductor device according to one or more embodiments. A operation of forming a conductive substrate according to the present embodiment explains an example of introducing a metal substrate as a conductive substrate as illustrated in FIGS. 1 to 3.

Referring to FIG. 9A, a first bonding metal layer 190 may be applied to a grinded surface of the first conductivity-type substrate 101 of the result obtained in FIG. 7C, and a second bonding metal layer 290 may be formed on an upper surface of a metal substrate 250.

The metal substrate 250 may include a metal or alloy with high conductivity. The metal substrate 250 may include Cu, Al, AlSiC, CuMo, CuW, Cu/CuMo/Cu, Cu/Mo/Cu, or Cu/W/Cu. In some embodiments, the metal substrate 250 may include an alloy whose thermal expansion coefficient is similar to a thermal expansion coefficient of the first conductive substrate 101. For example, the metal substrate 250 may include CuW, or Cu/Mo/Cu.

The first and second bonding metal layers 190 and 290 may include a eutectic metal, respectively. In some embodiments, the first and second eutectic metal layers 190 and 290 may include the same eutectic metal. For example, the first and second bonding metal layers 190 and 290 may include AuSn, NiSn, AgSn, Cr/NiSnTiAu, Ti/PtSnIn, or Ti/PtSnTiAu. The result obtained in FIG. 7C may be disposed on the metal substrate 250 so that the first bonding metal layer 190 of the first conductivity-type substrate 101 and the second bonding metal layer 290 of the metal substrate 250 face each other.

Next, referring to FIG. 9B, the metal substrate 250 may be bonded to the lower surface of the first conductivity-type substrate 101 using the first and second bonding metal layers 190 and 290.

The first and second bonding metal layers 190 and 290 may be bonded at a relatively low melting point through a eutectic reaction at a temperature of 250° C. or higher. This bonding operation can be performed with constant pressure applied. The first and second bonding metal layers 190 and 290 may be formed of a bonding metal layer BL by the above-described eutectic reaction. This bonding metal layer BL may mechanically couple the first conductivity-type substrate 101 and the metal substrate 250 to each other, and may be electrically connected to the metal substrate 250 with low contact resistance.

Next, referring to FIG. 9C, the carrier substrate 310 may be removed from the upper surface of the first conductivity-type substrate 101 by applying energy to the temporary bonding layer 320.

The removal of the carrier substrate 310 may be performed by applying energy (e.g., heat or ultraviolet rays) to the temporary bonding layer 320. When the temporary bonding layer 320 is a photosensitive adhesive layer, for example, ultraviolet light may be irradiated to the temporary bonding layer 320 through the light-transmitting substrate 310, and the temporary bonding layer 320 may be cured and adhesive strength may be removed or weakened, so that the carrier substrate 310 may be removed from the upper surface of the first conductivity-type substrate 101.

Next, referring to FIG. 9D, the first conductivity-type substrate 101 to which the metal substrate 250 is bonded may be cut to obtain the plurality of power semiconductor devices 100S.

The plurality of power semiconductor devices 100S obtained in this operation may respectively be the power semiconductor devices 100 shown in FIGS. 1 to 3. In the power semiconductor device 100S, the thickness (t1) of the first conductivity-type substrate 101 having a relatively high resistance may be reduced, and the metal substrate 250 may be reduced, so that the resistance between the source electrode and the drain electrode (i.e., on-resistance) may be improved.

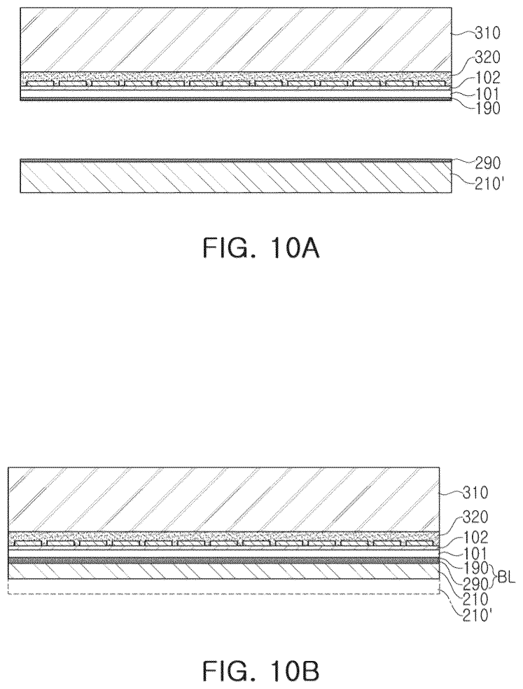

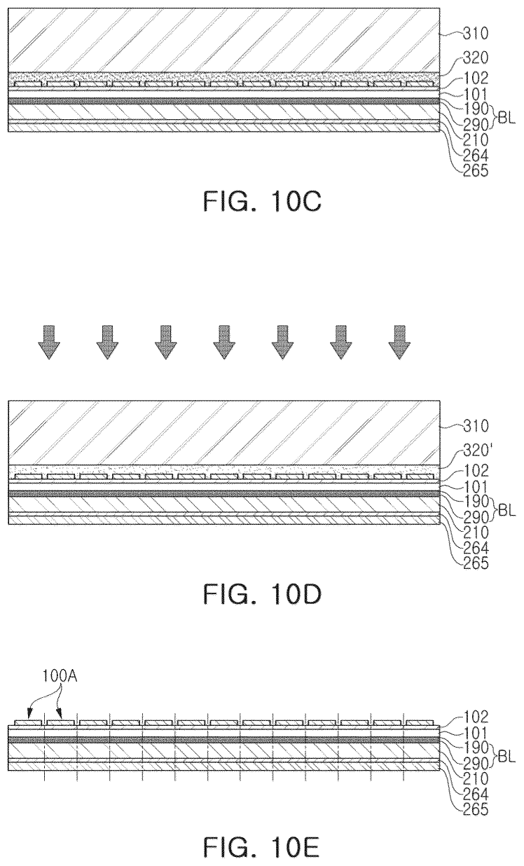

FIGS. 10A to 10E are cross-sectional views for each main operation illustrating some other operations of the method of manufacturing a power semiconductor device according to one or more embodiments. A operation of forming a conductive substrate according to the present embodiment explains an example of introducing a low-resistance semiconductor substrate as a conductive substrate, as illustrated in FIGS. 4 to 6.

Referring to FIG. 10A, a first bonding metal layer 190 may be applied to the grinded surface of the first conductivity-type substrate 101 of the result obtained in FIG. 7C, and a second bonding metal layer 290 may be formed on an upper surface of a low-resistance semiconductor substrate 210.

The low-resistance semiconductor substrate 210 used as a conductive substrate in the embodiment may be a silicon substrate doped with a specific conductivity-type impurity at a relatively high concentration (e.g., greater than or equal to 10¹⁹/cm²). The low-resistance semiconductor substrate 210 may have resistivity of less than or equal to about 0.05 Ω·cm. For example, the low-resistance semiconductor substrate 210 may be a semiconductor substrate doped with N-type impurities to greater than or equal to about 2×10¹⁹/cm².

Each of the first and second bonding metal layers 190 and 290 may include a eutectic metal. In some embodiments, the first and second eutectic metal layers 190 and 290 may include the same eutectic metal. For example, the first and second bonding metal layers 190 and 290 may include AuSn, NiSn, AgSn, Cr/NiSnTiAu, Ti/PtSnIn, or Ti/PtSnTiAu. The result obtained in FIG. 7C may be disposed on a metal substrate 250 so that the first bonding metal layer 190 of the first conductivity-type substrate 101 and the second bonding metal layer 290 of the metal substrate 250 face each other. In some embodiments, contact resistance may be improved by additionally forming a metal-semiconductor compound layer on an upper surface of a low-resistance semiconductor substrate on which a second bonding metal layer 290 is to be formed.

Next, referring to FIG. 10B, the low-resistance semiconductor substrate 210 may be bonded to the lower surface of the first conductivity-type substrate 101 using the first and second bonding metal layers 190 and 290. The first and second bonding metal layers 190 and 290 may be bonded at a low melting point through a eutectic reaction at a temperature of 250° C. or higher. This bonding operation may be performed with constant pressure applied.

The first and second bonding metal layers 190 and 290 may be formed of a bonding metal layer BL by the above-described eutectic reaction. This bonding metal layer BL can mechanically couple the first conductive substrate 101 and the low-resistance semiconductor substrate 210 to each other, and may be electrically connected to the low-resistance semiconductor substrate 210 with low contact resistance. An additional grinding operation may be applied to reduce the thickness of the low-resistance semiconductor substrate 210.

Next, referring to FIG. 10C, a metal-semiconductor compound layer 264 and a drain electrode layer 260 may be formed on a lower surface of the low-resistance semiconductor substrate 210.

Before the cutting, a drain electrode layer 260 may be formed on the lower surface of the low-resistance semiconductor substrate 210. The drain electrode layer 260 may include a metal material, for example, at least one of nickel (Ni), aluminum (Al), titanium (Ti), silver (Ag), vanadium (V), tungsten (W), cobalt (Co), molybdenum (Mo), copper (Cu), and ruthenium (Ru). In some embodiments, a metal-semiconductor compound layer 264 may be formed between the low-resistance semiconductor substrate 210 and the drain electrode layer 260. In one example, the metal-semiconductor compound layer 264 may be formed spontaneously during the operation of forming the drain electrode layer 260, but in another example, an annealing operation may be additionally performed to form the metal-semiconductor compound layer 264. The metal-semiconductor compound layer 264 may include, for example, at least one of TiSi, CoSi, MoSi, LaSi, NiSi, TaSi, or Wsi.

Next, referring to FIG. 10D, energy may be applied to the temporary bonding layer 320 to remove the carrier substrate 310 from an upper surface of the first conductivity-type substrate 101.

The removal of the carrier substrate 310 may be performed by applying energy (e.g., heat or ultraviolet rays) to the temporary bonding layer 320. When the temporary bonding layer 320 is a photosensitive adhesive layer, for example, ultraviolet light may be emitted to the temporary bonding layer 320 through the light-transmitting substrate 310, and the temporary bonding layer 320 may be cured and adhesive strength may be lost or weakened, so that the carrier substrate 310 can be removed from the upper surface of the first conductivity-type substrate 101.

Next, referring to FIG. 10E, a plurality of power semiconductor devices 100S may be obtained by cutting the result obtained in FIG. 10D.

The plurality of power semiconductor devices 100S obtained in this operation may be the power semiconductor devices 100A shown in FIGS. 4 to 6, respectively. Driving voltage characteristics of the power semiconductor device 100A may be improved, by reducing the thickness t1 of the first conductivity-type substrate 101 having a relatively high resistance in the power semiconductor device 100S and introducing the low-resistance semiconductor substrate 210.

As set forth above, according to the above-described embodiments, the power semiconductor device may significantly improve electrical characteristics such as on-resistance (Ron), by introducing a low-resistance conductive substrate while reducing a thickness of the SiC substrate having a first conductivity type.

The various and advantageous advantages and effects are not limited to the above description, and may be more easily understood in the course of describing embodiments.

While embodiments have been shown and described above, it will be apparent to those skilled in the art that modifications and variations could be made without departing from the scope of the present inventive concept as defined by the appended claims and their equivalents.

1. A power semiconductor device, comprising:
a silicon carbide (SiC) substrate having a first conductivity type;
a drift layer comprising a first conductivity type SiC on the SiC substrate;
a well region having a second conductivity type on the drift layer;
a source region having the first conductivity type on the well region;
a gate electrode on a portion of the drift layer and a portion of the well region;
a gate insulating layer between the gate electrode and the well region;
an interlayer insulating layer on the gate electrode and the source region;
a source electrode on the interlayer insulating layer connected to the source region through the interlayer insulating layer;
a conductive substrate on a lower surface of the SiC substrate; and
a bonding metal layer between the SiC substrate and the conductive substrate.

2. The power semiconductor device of claim 1, wherein a thickness of the SiC substrate is less than or equal to 150 μm.

3. The power semiconductor device of claim 1, wherein a thickness of the drift layer is in a range of 2 μm to 20 μm.

4. The power semiconductor device of claim 1, wherein the conductive substrate comprises a metal substrate.

5. The power semiconductor device of claim 4, wherein the conductive substrate comprises at least one of Cu, Al, AlSiC, CuMo, CuW, Cu/CuMo/Cu, Cu/Mo/Cu, and Cu/W/Cu.

6. The power semiconductor device of claim 1, wherein the conductive substrate comprises a low-resistance semiconductor substrate doped with impurities.

7. The power semiconductor device of claim 6, wherein a resistivity of the conductive substrate is less than or equal to 0.05 Ω·cm.

8. The power semiconductor device of claim 6, further comprising:
a metal-semiconductor compound layer on a lower surface of the conductive substrate, and
a drain electrode layer on the metal-semiconductor compound layer.

9. The power semiconductor device of claim 1, wherein the bonding metal layer comprises a eutectic metal layer.

10. The power semiconductor device of claim 9, wherein the bonding metal layer comprises AuSn, NiSn, AgSn, Cr/NiSnTiAu, Ti/PtSnIn, or Ti/PtSnTiAu.

11. The power semiconductor device of claim 1, further comprising:
a metal-semiconductor compound layer between the source region and the source electrode.

12. The power semiconductor device of claim 1, wherein the gate electrode and the well region have a first stripe pattern and a second stripe pattern, which are disposed alternately, respectively.

13. The power semiconductor device of claim 1, wherein a stack of the well region and the source region is divided into a plurality of stacks by a trench region having a depth extending to a portion of a drift region, and
wherein the gate electrode is in the trench region and on sides of the plurality of stacks.

14. The power semiconductor device of claim 13, wherein the plurality of trench regions have a hexagonal cross-sectional shape.

15. A power semiconductor device, comprising:
a silicon carbide (SiC) substrate having a first conductivity type and a thickness less than or equal to 100 μm;
a drift layer comprising a first conductivity type SiC on the SiC substrate;
a well region having a second conductivity type extending into the drift layer from an upper surface of the drift layer;
a source region having the first conductivity type extending into the well region from an upper surface of the well region;
a gate electrode on a portion of the drift layer and a portion of the well region;
a gate insulating layer between the gate electrode and the well region;
an interlayer insulating layer on the gate electrode and the source region;
a source electrode on the interlayer insulating layer connected to the source region through the interlayer insulating layer;
a metal substrate on a surface of the SiC substrate, as the metal substrate being a drain electrode; and
a bonding metal layer between the SiC substrate and the metal substrate.

16. The power semiconductor device of claim 15, wherein the metal substrate comprises CuW or Cu/Mo/Cu.

17. The power semiconductor device of claim 15, wherein the bonding metal layer comprises AuSn, NiSn, AgSn, Cr/NiSnTiAu, Ti/PtSnIn, or Ti/PtSnTiAu.

18. The power semiconductor device of claim 15, wherein a thickness of the SiC substrate is less than or equal to 80 μm.

19. A power semiconductor device, comprising:
a silicon carbide (SiC) substrate having a first conductivity type having a thickness less than or equal to 100 μm;
a drift layer comprising a first conductivity type SiC on the SiC substrate;
a well region having a second conductivity type extending into the drift layer from an upper surface of the drift layer;
a source region having the first conductivity type extending into the well region from an upper surface of the well region;
a gate electrode on a portion of the drift layer and a portion of the well region;
a gate insulating layer between the gate electrode and the well region;
an interlayer insulating layer on the gate electrode and the source region;
a source electrode on the interlayer insulating layer connected to the source region through the interlayer insulating layer;
a low-resistance semiconductor substrate on a surface of the SiC substrate, and doped with a first conductivity-type impurity;
a bonding metal layer between the SiC substrate and the low-resistance semiconductor substrate;
a metal-semiconductor compound layer on a surface of the low-resistance semiconductor substrate; and
a drain electrode layer on the metal-semiconductor compound layer.

20. The power semiconductor device of claim 19, wherein a resistivity of the low-resistance semiconductor substrate is less than or equal to 0.05 Ω·cm.

21-25. (canceled)
